(19) United States
(12) Patent Application Publication
(10) Pub. No.: US 2024/0155810 A1
(43) Pub. Date: May 9, 2024

(54) EVAPORATING CONCAVE-CONVEX PLATFORM STRUCTURE OF VAPOR CHAMBER AND MANUFACTURING METHOD THEREOF

(71) Applicant: JWS TECHNOLOGY CO., LTD., New Taipei City (TW)

(72) Inventors: Pang-Hung LIAO, New Taipei City (TW); Chih-Wei CHEN, New Taipei City (TW)

(21) Appl. No.: 17/983,718

(22) Filed: Nov. 9, 2022

(51) Int. Cl. H05K 7/20

(52) U.S. Cl. CPC H05K 7/2039

(57) ABSTRACT

An evaporating concave-convex platform structure of a vapor chamber and a manufacturing method thereof, the structure include a lower plate and an upper plate. The lower plate includes a main plate member and a concave-convex member. The main plate member has a chamber portion dented from one surface thereof and a frame edge surrounding a periphery of the chamber portion. The upper plate is stacked on the lower plate facing a dented surface of the chamber portion. The concave-convex member has a concave-convex surface disposed protrusively from the chamber portion of the lower plate or disposed concavely toward the chamber portion. A connecting portion is disposed to surrounds a periphery of the concave-convex surface. The connecting portion is stacked on the main plate member through the concave-convex surface. The connecting portion is welded to the main plate member.

### BACKGROUND

### Technical Field

The disclosure relates to a vapor chamber and a manufacturing method thereof, particularly to an evaporating concave-convex platform structure of a vapor chamber and a manufacturing method thereof.

### Description of Related Art

A related-art vapor chamber is composed of two metal plates which are welded to form a vacuum conductor with an inner portion in a hollow type. A surface of the vapor chamber is used to be flatly attached on a heat source to absorb heat and then the absorbed heat is thermally exchanged by another surface with condensation for heat dissipation.

However, the related art electronic products usually rely on multiple chips to make a multiplex process, so the circuit board is usually disposed with multiple and different heating elements, and the arranging thickness or heights are not the same. Thus, a single vapor chamber cannot cover all electronic heating elements on a circuit board by enlarging its plate area. To solve the problem, a related-art vapor chamber is usually formed with one or more protrusive platforms on the lower plate by machining, such as stamping or cutting, to serve as a contact with heat sources so as to allow a single vapor chamber to be used corresponding to multiple heat sources.

However, the abovementioned related-art protrusive platform structure of vapor chamber generally makes the protrusive platform structure be an integrated piece or composition with the lower plate to reduce the problem of possible leakage after sealing of the vapor chamber. Because of this, for example, forming the protrusive platform on the lower plate by stamping, the protrusive platform being stamped has a limitation in protrusive size, and even the plate thickness of the lower plate itself has certain limitation which cannot be too thin. Also, by means of cutting or casting, the machining process is time consuming, and particularly, the cutting may waste excessive material costs and may be difficult to accomplish the requirement of thinning of vapor chamber.

In view of this, the inventors have devoted themselves to the above-mentioned related art, researched intensively and cooperated with the application of science to try to solve the above-mentioned problems. Finally, the invention which is reasonable and effective to overcome the above drawbacks is provided.

### SUMMARY

An object of the disclosure is to provide an evaporating concave-convex platform structure of a vapor chamber and a manufacturing method thereof, which make the lower plate and the protrusive platform be closely connected to constitute a vapor chamber through a connecting manner. The connecting manner is implemented by welding such as diffusion welding, friction welding or high frequency welding to make connection so as to accomplish the material flexibility of workpieces in manufacturing.

Another object of the disclosure is to provide an evaporating concave-convex platform structure of a vapor chamber and a manufacturing method thereof, which the protrusive platform is formed by a dented concave platform structure in a reverse arrangement so as to increase the extensiveness of applicable circumstances and the variability of matching the applicable circumstances.

To accomplish the above objects, the disclosure provides an evaporating concave-convex platform structure of a vapor chamber, which includes a lower plate and an upper plate. The lower plate includes a main plate member and at least one concave-convex member disposed on the main plate member. The main plate member has a chamber portion dented from one surface thereof and a frame edge surrounding a periphery of the chamber portion. The upper plate is stacked on the lower plate facing a dented surface of the chamber portion of the lower plate. The concave-convex member has a concave-convex surface disposed protrusively from the chamber portion of the lower plate or disposed concavely toward the chamber portion. A connecting portion is disposed to surrounds a periphery of the concave-convex surface. The connecting portion is stacked on the main plate member through the concave-convex surface disposed protrusively from the chamber portion of the lower plate or disposed concavely toward the chamber portion.

To accomplish the above objects, the disclosure provides a manufacturing method of an evaporating concave-convex platform structure of a vapor chamber, which includes the steps of:
a) preparing a lower plate, wherein the lower plate includes a main plate member and at least one concave-convex member disposed on the main plate member, and the main plate member includes a chamber portion dented from one surface thereof and a frame edge surrounding a periphery of the chamber portion; and
b) preparing an upper plate and stacking the upper plate on the lower plate facing a dented surface of the chamber portion of the lower plate;
wherein the concave-convex member in the a) has a concave-convex surface disposed protrusively from the chamber portion of the lower plate or disposed concavely toward the chamber portion, a connecting portion is disposed to surrounds a periphery of the concave-convex surface, and the connecting portion is welded to the main plate member through the concave-convex surface disposed protrusively from the chamber portion of the lower plate or disposed concavely toward the chamber portion.

### BRIEF DESCRIPTION OF THE DRAWINGS

FIG. 1 is a perspective exploded view of the first embodiment of the disclosure;

FIG. 2 is a perspective assembled view from another viewpoint of the first embodiment of the disclosure;

FIG. 3 is an operational schematic view of the first embodiment of the disclosure in association with a jig;

FIG. 4 is an assembled schematic view of the first embodiment of the disclosure in association with a jig;

FIG. 5 is a cross-sectional schematic view of the sealing of the upper plate and the lower plate of the first embodiment of the disclosure in association with a jig

FIG. 6 is an operational schematic view of the second embodiment of the disclosure in association with a jig;

FIG. 7 is an operational schematic view of the third embodiment of the disclosure in association with a jig;

FIG. 8 is an operational schematic view of the fourth embodiment of the disclosure in association with a jig;

FIG. 9 is a cross-sectional schematic view of the fifth embodiment of the disclosure; and

FIG. 10 is a flowchart of manufacturing a vapor chamber with the disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

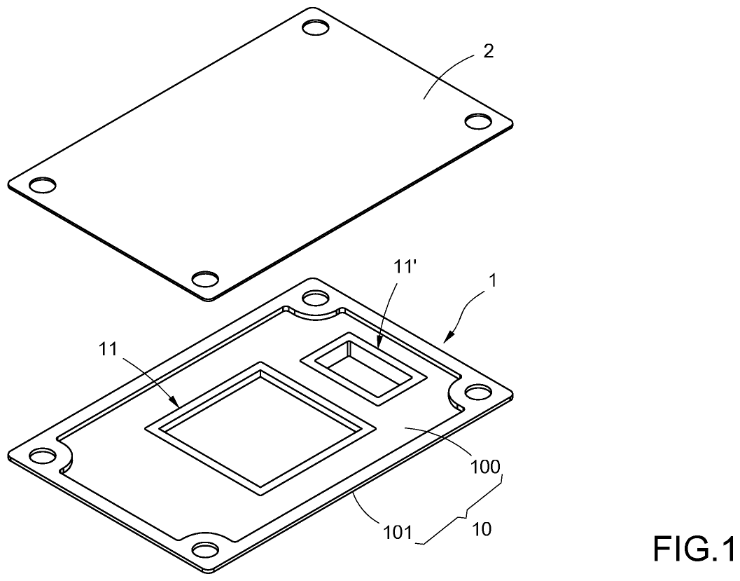

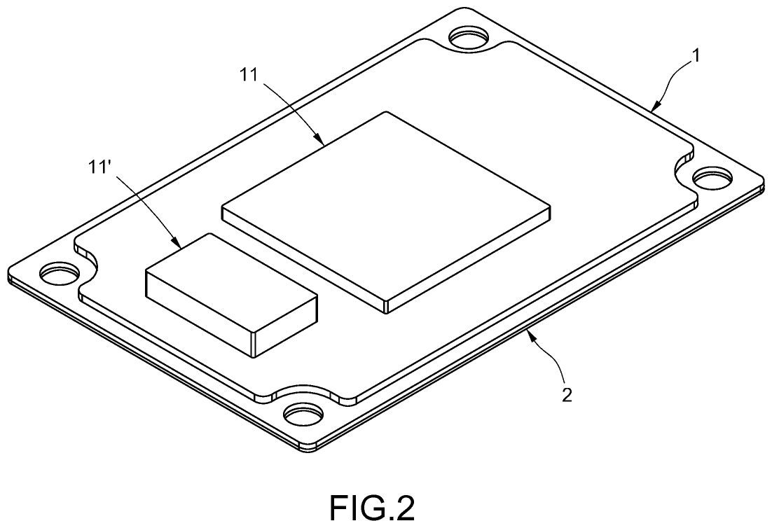

Please refer to FIGS. 1 and 2, which are a perspective exploded view of the first embodiment and a perspective assembled view from another viewpoint of the first embodiment of the disclosure. The disclosure provides an evaporating concave-convex platform structure of a vapor chamber and a manufacturing method thereof. The evaporating concave-convex platform structure of the vapor chamber includes a lower plate 1 and an upper plate 2 covering the lower plate 1.

The lower plate 1 includes a main plate member 10 and at least one concave-convex member 11, 11′ disposed on the main plate member 10. The main plate member 10 has a chamber portion 100 dented from one surface thereof (projecting from another surface thereof) and a frame edge 101 surrounding a periphery of the chamber portion 100. The upper plate 2 is corresponding to the shape of the lower plate 1 and stacked on the lower plate 1 facing a dented surface of the chamber portion 100. The upper plate 2 is closely connected (or sealed) with the frame edge 101 of the lower plate 1 to constitute a vapor chamber. In other embodiments, the lower plate 1 and the upper plate 2 may be matched by other shapes or sizes, so they are not limited to the same shape and size. Further, the inner surface of the upper plate 2 and the inner surface of the chamber portion 100 of the lower plate 1 may be separately disposed with a wick structure (not shown in figures) formed by metal mesh or sintered powder to manufacture the vapor chamber by the process such as degassing or vacuuming.

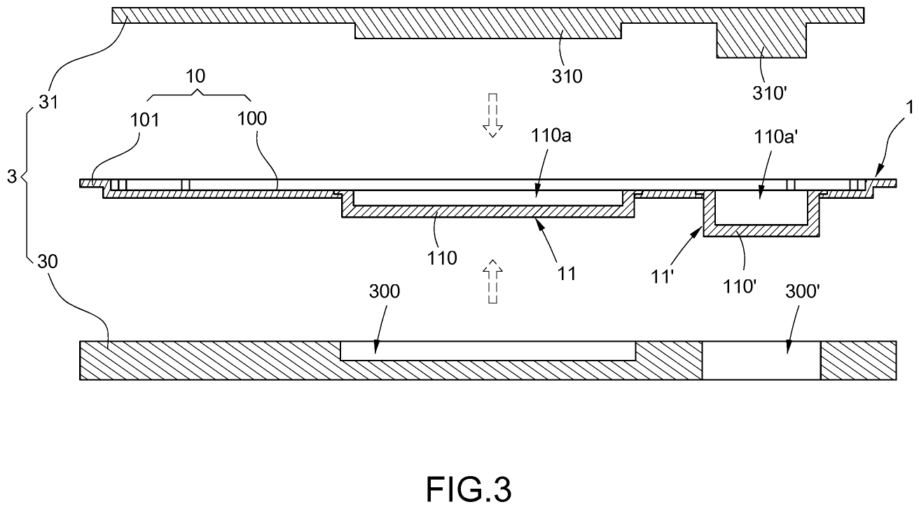

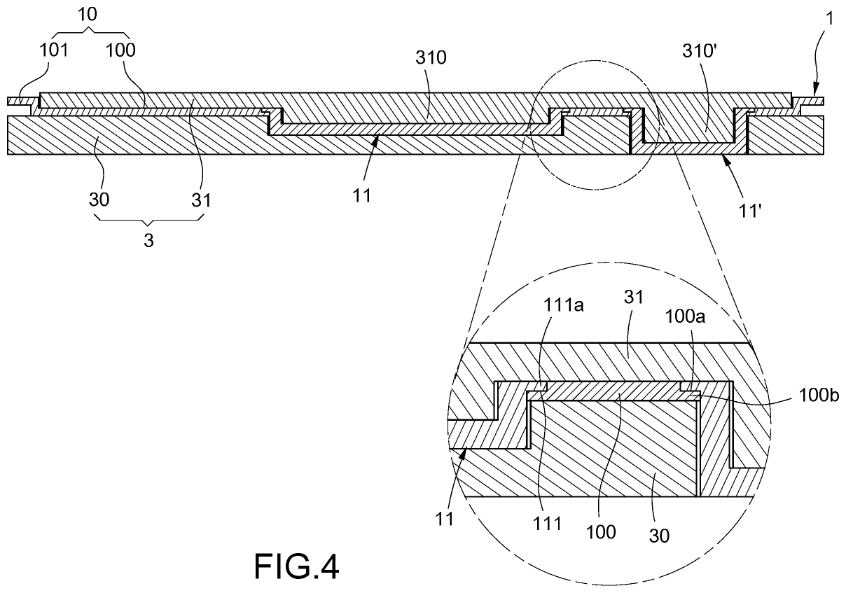

Please refer to FIGS. 3 and 4. The main plate member 10 of the lower plate 1 may be arranged with the concave-convex members 11, 11′ corresponding to different heat sources (not shown in figures). Each concave-convex member 11, 11′ has a concave-convex surface 110, 110′ projecting from the chamber portion 100 and an evaporating area 110a, 110a′ formed concavely in the concave-convex surface 110, 110′. In the embodiments of the disclosure, the concave-convex surfaces 110, 110′ of the concave-convex members 11, 11′ may have different heights depending upon actual requirements. For example, when a corresponding heat source has a higher relative position (or an electronic chip itself has a thicker thickness), the protruding height of the concave-convex surface 110 relative to the main plate member 10 is smaller. Contrarily, when a corresponding heat source has a lower relative position (or an electronic chip itself has a thinner thickness), the protruding height of the concave-convex surface 110 relative to the main plate member 10 is larger. As a result, the concave-convex members 11, 11′ may make the single vapor chamber be capable of simultaneously corresponding to heat sources with different heights to collectively solve the cooling problem of multiple heat sources.

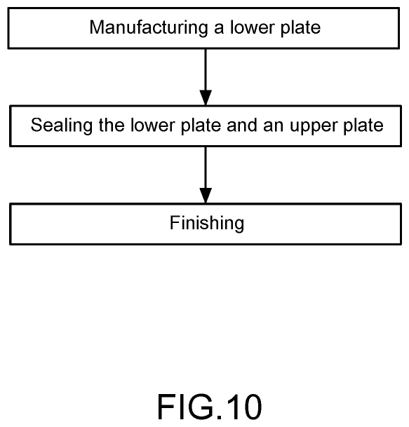

The disclosure uses welding, such as diffusion welding, friction welding or high frequency welding, to connect the main plate member 10 of the lower plate 1 and the concave-convex members 11, 11′ to constitute a complete lower plate 1 and seal that with the upper plate 2 to finish a vapor chamber (as the steps shown in FIG. 10). As shown in FIG. 3, when manufacturing the lower plate 1, the lower plate 1 is divided into a main plate member 10 and at least one concave-convex member 11, 11′. The main plate member 10 is formed with an arranging hole on the wall of the chamber portion 100 for the concave-convex member 11 to pass through. A periphery of the concave-convex surface 110 of the concave-convex member 11 is formed with a connecting portion 111 (continuously surrounding the concave-convex surface 110) to make the connecting portion 111 be stacked on the main plate portion 10 after the concave-convex surface 110 of the concave-convex member 11 protrudes from the chamber portion 100. Furthermore, the main plate member 10 is formed with a connected portion 100a connected with the connecting portion 111.

In the first embodiment of the disclosure, as shown in FIG. 4, the connecting portion 111 is located on a lower side of an outer edge 111a disposed protrusively from the concave-convex member 11, an inner surface of the corresponding arranging hole of the main plate member 10 is formed with an inner edge 100b for the outer edge 111a to be connected, and the connected portion 100a is formed on an upper place of the inner surface 100b. Also, when welding, a jig 3 may be used to position the main plate member 10 and each the concave-convex member 11, 11′. The jig 3 may include a lower mold 30 and an upper mold 31. The lower mold 30 separately has the concave receiving portions 300, 300′ corresponding to each concave-convex surface 110, 110′ of the concave-convex members 11, 11′. The upper mold 31 separately has the convex limiting portions 310, 310′ corresponding to the evaporating area 110a, 110a′ of each concave-convex member 11 to align and position the connecting portion 111 with the connected portion 100a so as to accurately proceed the welding process to connect the main plate member 10 with the concave-convex members 11, 11′ to be the lower plate 1.

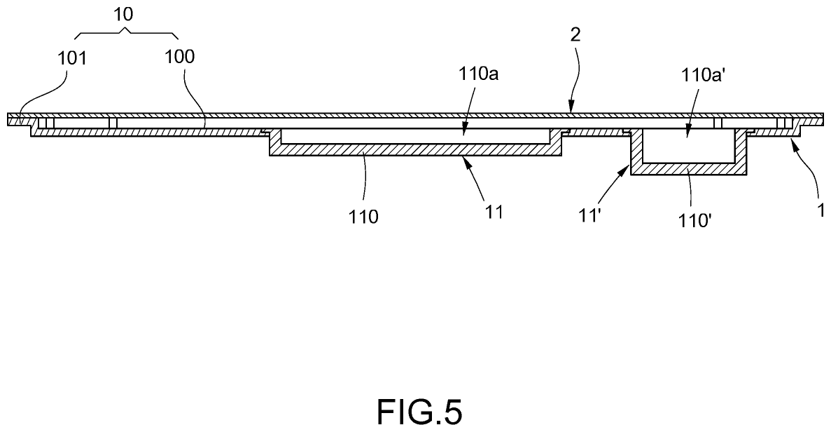

Next, as shown in FIG. 5, the lower plate 1 may be produced by the above process, so the upper plate 2 and the lower plate 1 may be sealed to finish the vapor chamber. As abovementioned, the inner surface of the upper plate 2 and the inner surface of the chamber portion 100 of the lower plate 1 may be separately disposed with a wick structure formed by metal mesh or sintered powder to manufacture the vapor chamber by the process such as degassing or vacuuming. The process is omitted here for brevity.

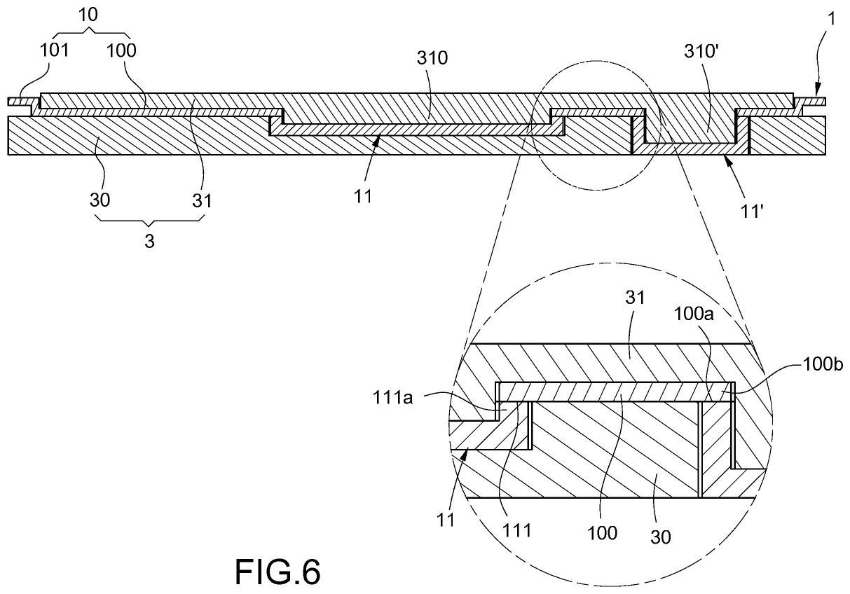

Moreover, as shown in FIG. 6, in the second embodiment of the disclosure, the connecting portion 111 may be directly formed on an outer edge 111a facing upward of each concave-convex member 11 and stacked with the connected portion 100a formed on the inner edge 100b of the arranging hole of the main plate member 10.

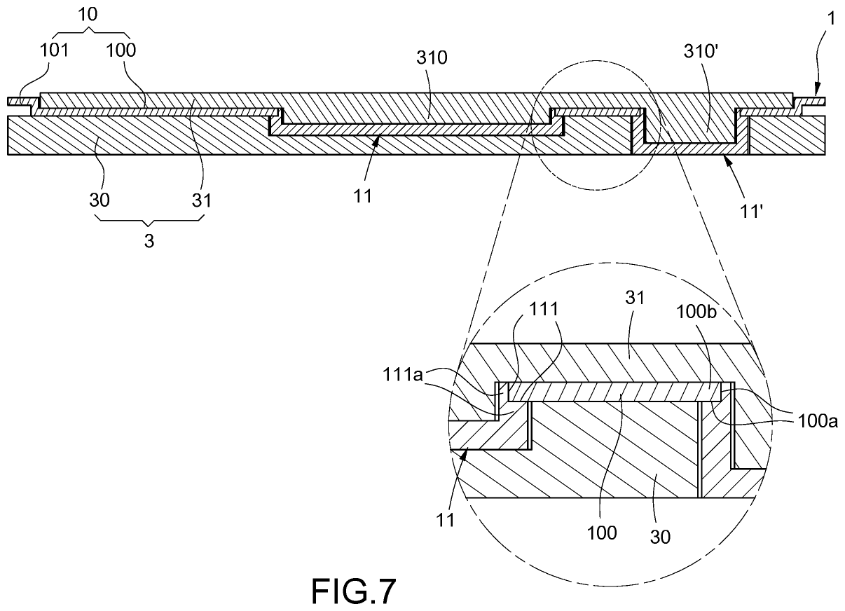

Also, as shown in FIG. 7, in the third embodiment of the disclosure, the connecting portion 111 may be formed on an annular place of an outer edge 111a in a step shape and stacked on the connected portion 100a formed on the inner edge 100b of the arranging hole of the main plate member 10.

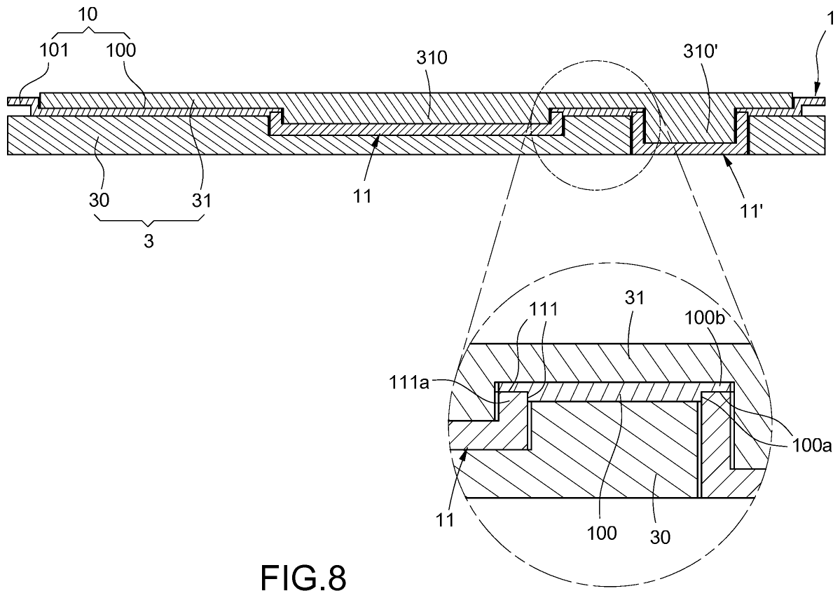

Also, as shown in FIG. 8, in the fourth embodiment of the disclosure, the connecting portion 111 is formed on an outer edge 111a facing upward of each concave-convex member 11, and the connected portion 100a is formed on a step-shaped annular place of the inner edge 100b of the arranging hole of the main plate member 10 to be stacked on the connecting portion 111.

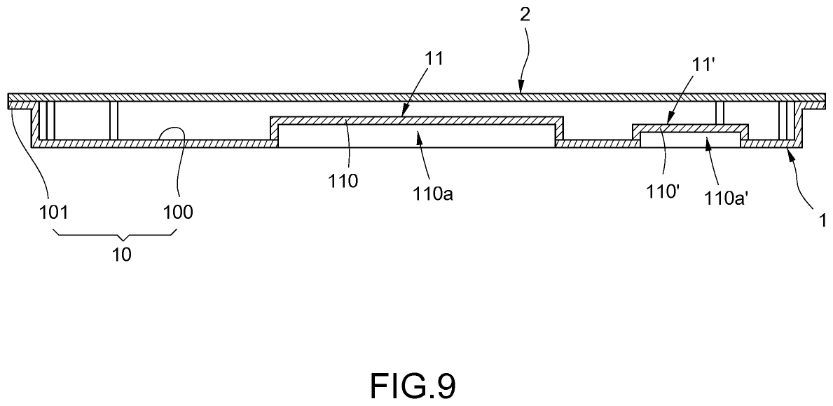

Also, as shown in FIG. 9, in the fifth embodiment of the disclosure, the concave-convex members 11, 11′ may be stacked and welded with the main plate member 10 in a manner of the concave-convex surface 110, 110′ being located in the chamber portion 100 of the lower plate 1. As a result, it may be applied to those circumstances which are limited in space. Also, it may be applied to multiple heat sources with great height differences, the concave-convex members 11, 11′ may be reversely arranged in a convex or concave manner to improve the extensiveness of applicable circumstances and the variability of matching the applicable circumstances.

Therefore, according to the embodiments shown in FIGS. 6-9, the connecting shapes of the main plate member 10 and each concave-convex member 11, 11′ of the disclosure, especially the geometrical matching shapes of the connecting portion 111 and the connected portion 100a, are not limited to those which are shown in the embodiments. It is understandable that the main plate member 10 and each concave-convex member 11, 11′ may be connected by welding such as diffusion welding, friction welding or high frequency welding as long as each concave-convex member 11, 11′ is formed with the connecting portion 111 which may be stacked with the main plate member 10 and the connecting portions 111 continuously surrounds a periphery of the concave-convex surfaces 110, 110′, so as to make the evaporating area 110a, 110a′ of each concave-convex member 11, 11′ communicate with the chamber portion 100 of the main plate member 10 to be a co-chamber mode and make each concave-convex member 11, 11′ be corresponding to the respective heat sources to perform heat exchange together.

As a result, by the abovementioned structure, the evaporating concave-convex platform structure of vapor chamber and the manufacturing method thereof may be obtained.

While this disclosure has been described by means of specific embodiments, numerous modifications and variations could be made thereto by those skilled in the art without departing from the scope and spirit of this disclosure set forth in the claims.

What is claimed is:

1. An evaporating concave-convex platform structure of a vapor chamber, the evaporating concave-convex platform structure comprising:
a lower plate, comprising a main plate member and at least one concave-convex member disposed on the main plate member, and the main plate member comprising a chamber portion dented from one surface thereof and a frame edge surrounding a periphery of the chamber portion; and
an upper plate, stacked on the lower plate facing a dented surface of the chamber portion of the lower plate;
wherein the concave-convex member comprises a concave-convex surface disposed protrusively from the chamber portion of the lower plate or disposed concavely toward the chamber portion, a connecting portion is disposed to surrounds a periphery of the concave-convex surface, and the connecting portion is stacked on the main plate member through the concave-convex surface disposed protrusively from the chamber portion of the lower plate or disposed concavely toward the chamber portion.

2. The evaporating concave-convex platform structure of claim 1, wherein the concave-convex member is multiple in number.

3. The evaporating concave-convex platform structure of claim 2, wherein the concave-convex members are different in height.

4. The evaporating concave-convex platform structure of claim 1, wherein the main plate member comprises an arranging hole defined on the chamber portion, and the concave-convex member passes through the arranging hole.

5. The evaporating concave-convex platform structure of claim 1, wherein the main plate member comprises a connected portion connected with the connecting portion.

6. The evaporating concave-convex platform structure of claim 1, wherein the connecting portion is located on a lower side of an outer edge disposed protrusively from the concave-convex member, and the main plate member comprises an inner edge connected with the outer edge.

7. The evaporating concave-convex platform structure of claim 1, wherein the connecting portion is located on an outer edge of the concave-convex member facing upward and stacked with a connected portion disposed on the main plate member.

8. The evaporating concave-convex platform structure of claim 1, wherein the connecting portion is located on an annular place of an outer edge in a step shape and stacked with a connected portion of the main plate member.

9. The evaporating concave-convex platform structure of claim 1, wherein the connecting portion is located on an outer edge of the concave-convex member facing upward, the main plate member comprises a connected portion connected with the connecting portion, and the connected portion is of a step shape and stacked on the connecting portion.

10. A manufacturing method of an evaporating concave-convex platform structure of a vapor chamber, the manufacturing method comprising:
a) preparing a lower plate, wherein the lower plate comprises a main plate member and at least one concave-convex member disposed on the main plate member, and the main plate member comprises a chamber portion dented from one surface thereof and a frame edge surrounding a periphery of the chamber portion; and
b) preparing an upper plate and stacking the upper plate on the lower plate facing a dented surface of the chamber portion of the lower plate;
wherein the concave-convex member in the a) comprises a concave-convex surface disposed protrusively from the chamber portion of the lower plate or disposed concavely toward the chamber portion, a connecting portion is disposed to surrounds a periphery of the concave-convex surface, and the connecting portion is welded to the main plate member through the concave-convex surface disposed protrusively from the chamber portion of the lower plate or disposed concavely toward the chamber portion.
